(19) United States
(12) Patent Application Publication
(10) Pub. No.: US 2012/0225194 A1
(43) Pub. Date: Sep. 6, 2012

(54) Apparatus And Process For Atomic Layer Deposition

(75) Inventor: Joseph Yudovsky, Campbell, CA (US)

(73) Assignee: Applied Materials, Inc., Santa Clara, CA (US)

(21) Appl. No.: 13/189,708

(22) Filed: Jul. 25, 2011

Related U.S. Application Data
(63) Continuation of application No. 13/038,061, filed on Mar. 1, 2011.

(51) Int. Cl. B05D 5/12; C23C 16/458

(52) U.S. Cl. 427/58; 118/719; 118/696; 901/30

(57) ABSTRACT

Provided are atomic layer deposition apparatus and methods including multiple gas distribution plates including stages for moving substrates between the gas distribution plates.

### STATEMENT OF RELATED CASES

This application is a continuation of U.S. patent application Ser. No. 13/038,061, filed Mar. 1, 2011, which is incorporated herein by reference.

### BACKGROUND

Embodiments of the invention generally relate to an apparatus and a method for depositing materials. More specifically, embodiments of the invention are directed to atomic layer deposition chambers with multiple gas distribution plates.

In the field of semiconductor processing, flat-panel display processing or other electronic device processing, vapor deposition processes have played an important role in depositing materials on substrates. As the geometries of electronic devices continue to shrink and the density of devices continues to increase, the size and aspect ratio of the features are becoming more aggressive, e.g., feature sizes of 0.07 μm and aspect ratios of 10 or greater. Accordingly, conformal deposition of materials to form these devices is becoming increasingly important.

During an atomic layer deposition (ALD) process, reactant gases are sequentially introduced into a process chamber containing a substrate. Generally, a first reactant is introduced into a process chamber and is adsorbed onto the substrate surface. A second reactant is then introduced into the process chamber and reacts with the first reactant to form a deposited material. A purge step may be carried out between the delivery of each reactant gas to ensure that the only reactions that occur are on the substrate surface. The purge step may be a continuous purge with a carrier gas or a pulse purge between the delivery of the reactant gases.

There is an ongoing need in the art for improved apparatuses and methods for rapidly processing multiple substrates by atomic layer deposition at the same time.

### SUMMARY

Embodiments of the invention are directed to deposition systems comprising a processing chamber with a plurality of gas distribution plates. Each of the gas distribution plates has a plurality of elongate gas ports configured to direct flows of gases toward a surface of a substrate. A stage is in the processing chamber for moving a substrate from a back end of one gas distribution plate to a front end of another gas distribution plate.

In some embodiments, the plurality of gas distribution plates are stacked in a vertical arrangement and the stage is configured to move vertically. In detailed embodiments, the plurality of gas distribution plates are aligned horizontally and the stage is configured to move horizontally.

In one or more embodiments, there are two gas distribution plates. In some embodiments, there are four gas distribution plates. In specific embodiments, the four gas distribution plates are separated into a first group of two gas distribution plates and a second group of gas distribution plates, and a different set of substrates can be processed on the first group than the second group of gas distribution plates.

Some embodiments further comprise a conveyer system adjacent to each of the plurality of gas distribution plates. The conveyer systems is configured to transport at least one substrate along an axis perpendicular to the elongate gas ports.

In one or more detailed embodiments, each of the gas distribution plates comprises a sufficient number of gas ports to process up to 27 atomic layer deposition cycles. In specific embodiments, each of the plurality of gas ports can be individually controlled.

In some embodiments, at least one of the plurality of gas ports in each of the plurality of gas distribution plates is in flow communication with a first precursor gas and at least one of the plurality of gas ports in each of the plurality of gas distribution plates is in flow communication with a second precursor gas.

Additional embodiments of the invention are directed to deposition systems comprising a processing chamber with four gas distribution plates. The gas distribution plates are stacked vertically. Each of the gas distribution plates has a plurality of elongate gas ports configured to direct flows of gases toward a surface of a substrate. At least two stages for moving a substrate between the four gas distribution plates are in the processing chamber.

Further embodiments of the invention are directed to methods of processing a substrate in a processing chamber. A substrate is laterally moved in a first direction adjacent a first gas distribution plate from a loading region through a first deposition region to a first non-deposition region opposite the loading region. The substrate is moved in a second direction perpendicular to the first direction from the first non-deposition region to a second non-deposition region adjacent to a second gas distribution plate. The substrate is laterally moved in a third direction parallel to and opposite the first direction, the substrate moving from the second non-deposition region through a second deposition region to a third non-deposition region opposite from the second non-deposition region. In detailed embodiments, the second direction is vertical. In specific embodiments, the second direction is horizontal.

In some embodiments, the substrate is loaded into the processing chamber from a load lock chamber to the loading region. In detailed embodiments, the substrate is unloaded from the third non-deposition region of the processing chamber to a load lock chamber.

Some embodiments of the method further comprise moving the substrate in a fourth direction opposite from the second direction. The substrate is moved from the second non-deposition region back to the loading region. The movements in the first direction, second direction and third direction to move the substrate back to the third non-deposition region is repeated. In detailed embodiments, substrate is removed from the processing chamber after the substrate has reached the third non-deposition region a second time.

Some embodiments of the method further comprise moving the substrate in a fourth direction perpendicular to the third direction. The substrate is moved from the third non-deposition region to a fourth non-deposition region adjacent to a third gas distribution plate. The substrate is laterally moved in a fifth direction parallel to the first direction. The substrate moves from the fourth non-deposition region through a third deposition region to a fifth non-deposition region opposite the fourth non-deposition region. The substrate is moved in a sixth direction perpendicular to the fifth direction, the substrate moving from the fifth non-deposition region to a sixth non-deposition region adjacent to a fourth gas distribution plate. The substrate is laterally moved in a seventh direction parallel to the third direction, the substrate moving from the sixth non-deposition region through a fourth deposition region to an eighth non-deposition region.

In detailed embodiments, one or more of the second direction, fourth direction and sixth direction are vertical. In specific embodiments, one or more of the second direction, fourth direction and sixth direction are horizontal.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic cross-sectional side view of an atomic layer deposition chamber according to one or more embodiments of the invention;

FIG. 2 shows a perspective view of a susceptor in accordance with one or more embodiments of the invention;

FIG. 3 shows a top view of a gas distribution plate in accordance with one or more embodiments of the invention;

FIG. 4 shows a schematic cross-sectional view of an atomic layer deposition chamber in accordance with one or more embodiments of the invention;

FIG. 5 shows a top view of an atomic layer deposition chamber in accordance with one or more embodiments of the invention; and

FIG. 6 shows a schematic cross-sectional view of an atomic layer deposition chamber in accordance with one or more embodiments of the invention.

### DETAILED DESCRIPTION

Embodiments of the invention are directed to atomic layer deposition apparatus and methods which provide improved movement of substrates. Specific embodiments of the invention are directed to atomic layer deposition (also referred to as cyclical deposition) apparatuses incorporating a gas distribution plate having a detailed configuration and reciprocal linear motion.

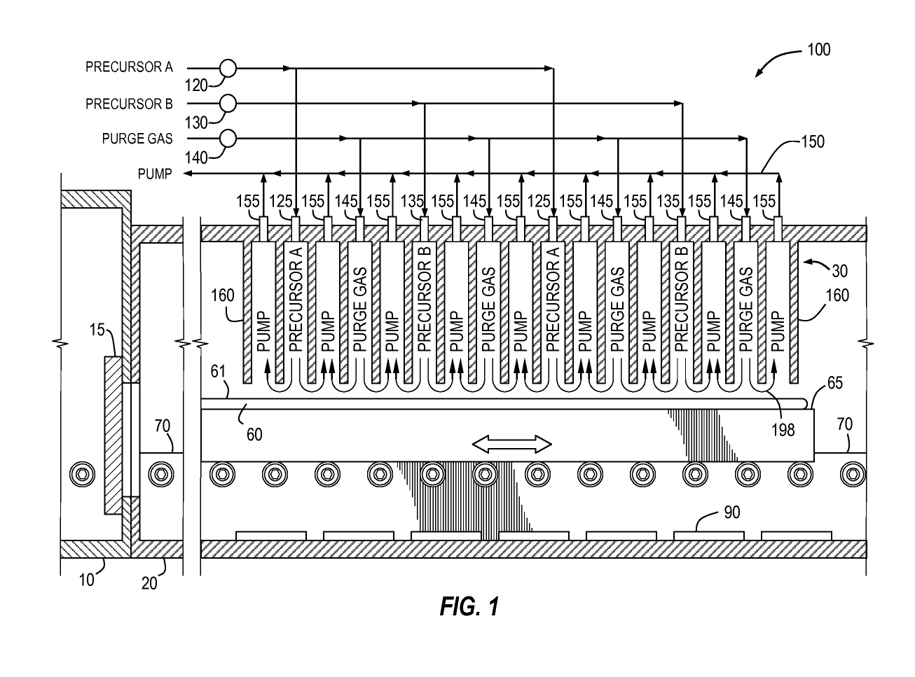

FIG. 1 is a schematic cross-sectional view of an atomic layer deposition system 100 or reactor in accordance with one or more embodiments of the invention. The system 100 includes a load lock chamber 10 and a processing chamber 20. The processing chamber 20 is generally a sealable enclosure, which is operated under vacuum, or at least low pressure. The processing chamber 20 is isolated from the load lock chamber 10 by an isolation valve 15. The isolation valve 15 seals the processing chamber 20 from the load lock chamber 10 in a closed position and allows a substrate 60 to be transferred from the load lock chamber 10 through the valve to the processing chamber 20 and vice versa in an open position.

The system 100 includes a gas distribution plate 30 capable of distributing one or more gases across a substrate 60. The gas distribution plate 30 can be any suitable distribution plate known to those skilled in the art, and specific gas distribution plates described should not be taken as limiting the scope of the invention. The output face of the gas distribution plate 30 faces the first surface 61 of the substrate 60.

Substrates for use with the embodiments of the invention can be any suitable substrate. In detailed embodiments, the substrate is a rigid, discrete, generally planar substrate. As used in this specification and the appended claims, the term “discrete” when referring to a substrate means that the substrate has a fixed dimension. The substrate of specific embodiments is a semiconductor wafer, such as a 200 mm or 300 mm diameter silicon wafer.

The gas distribution plate 30 comprises a plurality of gas ports configured to transmit one or more gas streams to the substrate 60 and a plurality of vacuum ports disposed between each gas port and configured to transmit the gas streams out of the processing chamber 20. In the detailed embodiment of FIG. 1, the gas distribution plate 30 comprises a first precursor injector 120, a second precursor injector 130 and a purge gas injector 140. The injectors 120, 130, 140 may be controlled by a system computer (not shown), such as a mainframe, or by a chamber-specific controller, such as a programmable logic controller. The precursor injector 120 is configured to inject a continuous (or pulse) stream of a reactive precursor of compound A into the processing chamber 20 through a plurality of gas ports 125. The precursor injector 130 is configured to inject a continuous (or pulse) stream of a reactive precursor of compound B into the processing chamber 20 through a plurality of gas ports 135. The purge gas injector 140 is configured to inject a continuous (or pulse) stream of a non-reactive or purge gas into the processing chamber 20 through a plurality of gas ports 145. The purge gas is configured to remove reactive material and reactive by-products from the processing chamber 20. The purge gas is typically an inert gas, such as, nitrogen, argon and helium. Gas ports 145 are disposed in between gas ports 125 and gas ports 135 so as to separate the precursor of compound A from the precursor of compound B, thereby avoiding cross-contamination between the precursors.

In another aspect, a remote plasma source (not shown) may be connected to the precursor injector 120 and the precursor injector 130 prior to injecting the precursors into the chamber 20. The plasma of reactive species may be generated by applying an electric field to a compound within the remote plasma source. Any power source that is capable of activating the intended compounds may be used. For example, power sources using DC, radio frequency (RF), and microwave (MW) based discharge techniques may be used. If an RF power source is used, it can be either capacitively or inductively coupled. The activation may also be generated by a thermally based technique, a gas breakdown technique, a high intensity light source (e.g., UV energy), or exposure to an x-ray source. Exemplary remote plasma sources are available from vendors such as MKS Instruments, Inc. and Advanced Energy Industries, Inc.

The system 100 further includes a pumping system 150 connected to the processing chamber 20. The pumping system 150 is generally configured to evacuate the gas streams out of the processing chamber 20 through one or more vacuum ports 155. The vacuum ports 155 are disposed between each gas port so as to evacuate the gas streams out of the processing chamber 20 after the gas streams react with the substrate surface and to further limit cross-contamination between the precursors.

The system 100 includes a plurality of partitions 160 disposed on the processing chamber 20 between each port. A lower portion of each partition extends close to the first surface 61 of substrate 60. For example, about 0.5 mm or greater from the first surface 61. In this manner, the lower portions of the partitions 160 are separated from the substrate surface by a distance sufficient to allow the gas streams to flow around the lower portions toward the vacuum ports 155 after the gas streams react with the substrate surface. Arrows 198 indicate the direction of the gas streams. Since the partitions 160 operate as a physical barrier to the gas streams, they also limit cross-contamination between the precursors. The arrangement shown is merely illustrative and should not be taken as limiting the scope of the invention. It will be understood by those skilled in the art that the gas distribution system shown is merely one possible distribution system and the other types of showerheads may be employed.

In operation, a substrate 60 is delivered (e.g., by a robot) to the load lock chamber 10 and is placed on a shuttle 65. After the isolation valve 15 is opened, the shuttle 65 is moved along the track 70. Once the shuttle 65 enters in the processing chamber 20, the isolation valve 15 closes, sealing the processing chamber 20. The shuttle 65 is then moved through the processing chamber 20 for processing. In one embodiment, the shuttle 65 is moved in a linear path through the chamber.

As the substrate 60 moves through the processing chamber 20, the first surface 61 of substrate 60 is repeatedly exposed to the precursor of compound A coming from gas ports 125 and the precursor of compound B coming from gas ports 135, with the purge gas coming from gas ports 145 in between. Injection of the purge gas is designed to remove unreacted material from the previous precursor prior to exposing the substrate surface 61 to the next precursor. After each exposure to the various gas streams (e.g., the precursors or the purge gas), the gas streams are evacuated through the vacuum ports 155 by the pumping system 150. Since a vacuum port may be disposed on both sides of each gas port, the gas streams are evacuated through the vacuum ports 155 on both sides. Thus, the gas streams flow from the respective gas ports vertically downward toward the first surface 61 of the substrate 60, across the substrate surface 61 and around the lower portions of the partitions 160, and finally upward toward the vacuum ports 155. In this manner, each gas may be uniformly distributed across the substrate surface 61. Arrows 198 indicate the direction of the gas flow. Substrate 60 may also be rotated while being exposed to the various gas streams. Rotation of the substrate may be useful in preventing the formation of strips in the formed layers. Rotation of the substrate can be continuous or in discreet steps.

Sufficient space is generally provided at the end of the processing chamber 20 so as to ensure complete exposure by the last gas port in the processing chamber 20. Once the substrate 60 reaches the end of the processing chamber 20 (i.e., the first surface 61 has completely been exposed to every gas port in the chamber 20), the substrate 60 returns back in a direction toward the load lock chamber 10. As the substrate 60 moves back toward the load lock chamber 10, the substrate surface may be exposed again to the precursor of compound A, the purge gas, and the precursor of compound B, in reverse order from the first exposure.

The extent to which the substrate surface 61 is exposed to each gas may be determined by, for example, the flow rates of each gas coming out of the gas port and the rate of movement of the substrate 60. In one embodiment, the flow rates of each gas are configured so as not to remove adsorbed precursors from the substrate surface 61. The width between each partition, the number of gas ports disposed on the processing chamber 20, and the number of times the substrate is passed back and forth may also determine the extent to which the substrate surface 61 is exposed to the various gases. Consequently, the quantity and quality of a deposited film may be optimized by varying the above-referenced factors.

In another embodiment, the system 100 may include a precursor injector 120 and a precursor injector 130, without a purge gas injector 140. Consequently, as the substrate 60 moves through the processing chamber 20, the substrate surface 61 will be alternately exposed to the precursor of compound A and the precursor of compound B, without being exposed to purge gas in between.

The embodiment shown in FIG. 1 has the gas distribution plate 30 above the substrate. While the embodiments have been described and shown with respect to this upright orientation, it will be understood that the inverted orientation is also possible. In that situation, the first surface 61 of the substrate 60 will face downward, while the gas flows toward the substrate will be directed upward.

In yet another embodiment, the system 100 may be configured to process a plurality of substrates. In such an embodiment, the system 100 may include a second load lock chamber (disposed at an opposite end of the load lock chamber 10) and a plurality of substrates 60. The substrates 60 may be delivered to the load lock chamber 10 and retrieved from the second load lock chamber. In one or more embodiments, at least one radiant heat lamp 90 is positioned to heat the second side of the substrate 60.

In some embodiments, the shuttle 65 is a susceptor 66 for carrying the substrate 60. Generally, the susceptor 66 is a carrier which helps to form a uniform temperature across the substrate. The susceptor 66 is movable in both directions (left-to-right and right-to-left, relative to the arrangement of FIG. 1) between the load lock chamber 10 and the processing chamber 20. The susceptor 66 has a top surface 67 for carrying the substrate 60. The susceptor 66 may be a heated susceptor so that the substrate 60 may be heated for processing. As an example, the susceptor 66 may be heated by radiant heat lamps 90, a heating plate, resistive coils, or other heating devices, disposed underneath the susceptor 66.

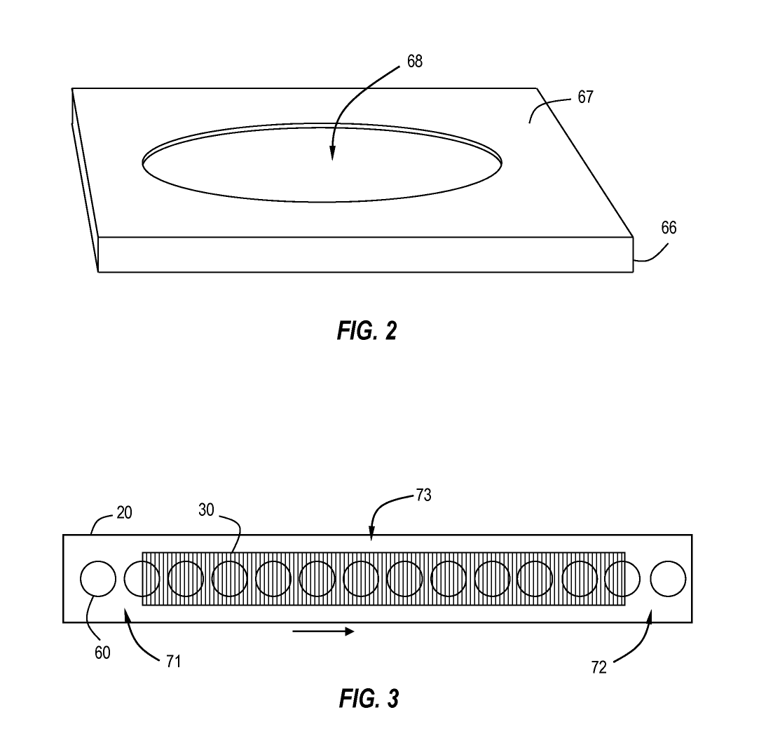

In still another embodiment, the top surface 67 of the susceptor 66 includes a recess 68 configured to accept the substrate 60, as shown in FIG. 2. The susceptor 66 is generally thicker than the thickness of the substrate so that there is susceptor material beneath the substrate. In detailed embodiments, the recess 68 is configured such that when the substrate 60 is disposed inside the recess 68, the first surface 61 of substrate 60 is level with the top surface 67 of the susceptor 66. Stated differently, the recess 68 of some embodiments is configured such that when a substrate 60 is disposed therein, the first surface 61 of the substrate 60 does not protrude above the top surface 67 of the susceptor 66.

FIG. 3 shows a top view of a processing chamber 20 in accordance with one or more embodiments of the invention. The processing chamber is connected to a load lock chamber (not shown) which is capable of loading multiple substrates 60 into the processing chamber 20. A gas distribution plate 30 is in the processing chamber 20. Substrates 60 travel a deposition path defined as being from the loading region 71 through a deposition region 73 to a non-deposition region 72 on the opposite side of the gas distribution plate 30 from the loading region 71. The substrates 60 are moved along the deposition path by a conveyer system (not shown). The conveyer system can be any suitable system known to those skilled in the art, including, but not limited to rollers (as seen in FIG. 1), a moving track and an air bearing. The gas distribution plate 30 of this embodiment is long enough to ensure that a substrate 60 passing through the entire deposition path will have a fully formed deposition layer. A fully formed deposition layer can include up to several hundred individual atomic layer deposition cycles. Each deposition cycle comprises contacting the substrate 60 surface with a first precursor A and a second precursor B, with optional other gases including purge gases. Many atomic layer deposition films are formed from about 48 individual cycles. To accommodate this number of cycles, or more, in a single pass through the deposition path, the gas distribution plate 30 will have at least 48 gas ports for precursor A, 48 gas ports for precursor B, 95 purge gas ports, and about 200 vacuum ports, resulting in a large gas distribution plate 30.

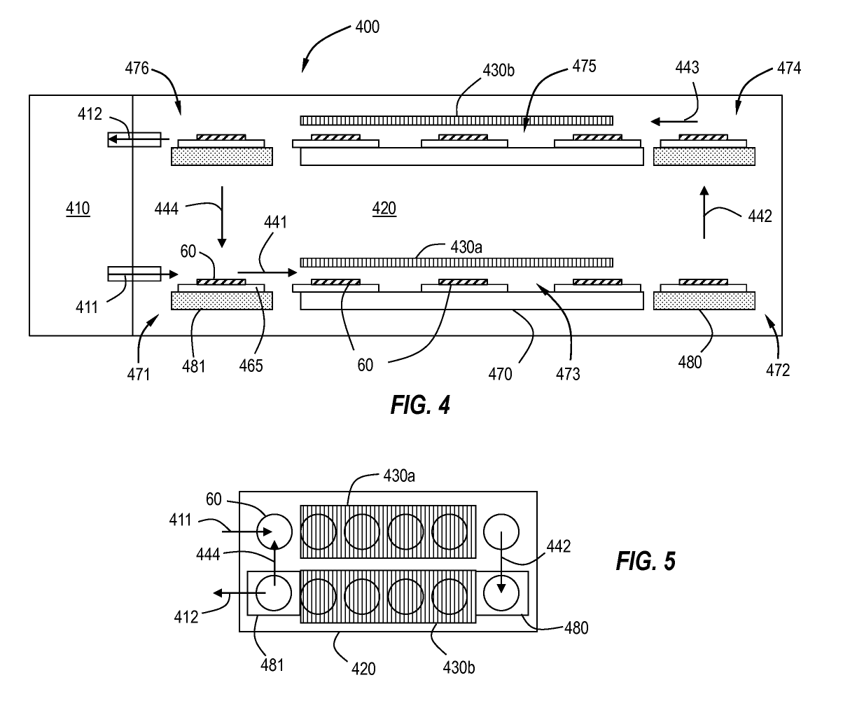

FIG. 4 shows a side view of a deposition system 400 in accordance with one or more embodiments of the invention. The deposition system 400 of some embodiments includes a load lock chamber 410 and a processing chamber 420. The processing chamber 420 shown has two gas distribution plates, a first gas distribution plate 430a and a second gas distribution plate 430b. Each of the gas distribution plates 430a, 430b has a plurality of elongate gas ports configured to direct flows of gases toward a surface of a substrate 60. While the embodiment shown has two gas distribution plates 430, it should be understood that the processing chamber 420 can accommodate any number of gas distribution plates 430.

Each of the gas distribution plates can have any suitable number of gas ports to deposit layers on the substrate. In detailed embodiments, each of the gas distribution plates comprises a sufficient number of gas ports to process up to 27 atomic layer deposition cycles. In specific embodiments, each of the gas distribution plates comprises a sufficient number of gas ports to process up to 50 atomic layer deposition cycles.

The processing chamber 420 may include a shuttle 465 or substrate carrier for moving the substrate 60 through one or more deposition path. The shuttle 465 can be any suitable device known to those in the art, including, but not limited to susceptors. The shuttle 465 of some embodiments supports the substrate 60 throughout the entire deposition process. In one or more embodiments, the shuttle 465 supports the substrate 60 through one or more portion of the deposition process. The processing chamber 420 may also include a conveyer system 470 adjacent to each of the plurality of gas distribution plates 430. The conveyer systems 470 is configured to transport at least one substrate 60 along an axis perpendicular to the elongate gas ports. In detailed embodiments, the conveyer 470 is configured to transport at least three substrates substantially simultaneously, meaning that three substrates or more are on the conveyer at any given time.

The plurality of gas distribution plates 430 can be arranged in any suitable configuration. In the embodiment of FIG. 4, the second gas distribution plate 430b is above and parallel to the first gas distribution plate 430a. In some embodiments, the second gas distribution plate 430b is below and parallel to the first gas distribution plate 430a. In detailed embodiments, one of the gas distribution plates is above and perpendicular to the other gas distribution plate.

The processing chamber 420 may include a stage 480 capable of horizontal and/or vertical movement. The stage 480 is configured to move the substrate 60 and any shuttle 465, if present, from the back end of the first gas distribution plate 430a to the beginning, or front end, of the second gas distribution plate 430b. As used in this specification and the appended claims, the term “back end” means a region adjacent to the gas distribution plate in a position which would be reached by a substrate after passing through the deposition region of the gas distribution plate, and the term “front end” means a region adjacent to a gas distribution plate in a position in which a substrate would depart from to pass through the deposition region. The stage 480 can be any suitable device including, but not limited to, platforms and forks. In detailed embodiments, the stage 480 is configured to move vertically. In specific embodiments, the stage 480 is configured to move horizontally. In one or more embodiments, the stage 480 is configured to move both horizontally and vertically. The stage can be connected to the processing chamber by any suitable means. In a detailed embodiment, the stage is attached to vertical rails which go up and down within the chamber. The stage may also include blades, or some wafer handling mechanism, extending from rails to hold the substrate.

The detailed embodiment of FIG. 4 has the plurality of gas distribution plates 430 stacked in a vertical arrangement and the stage 480 is configured to move vertically. The stage 480 is configured to lift the substrate 60 from the end of the first gas distribution plate 430a to the beginning of the second gas distribution plate 430b.

In operation, a substrate 60, which may be supported on a shuttle 465, is moved laterally in a first direction 441. The first direction 441 is adjacent to the first gas distribution plate 430a and moves the substrate 60 from a loading region 471 through a first deposition region 473 to a first non-deposition region 472 opposite the loading region 471. In passing through the first deposition region 473, at least one layer is deposited onto the surface of the substrate 60. In detailed embodiments, after passing through the first deposition region 473, there are in the range of about 10 to about 40 layers deposited on the surface of the substrate 60.

The substrate 60 is then moved in a second direction 442 perpendicular to the first direction 441 by a stage 480 configured to move, at least, in the second direction 442. This movement causes the substrate 60 to be moved from the first non-deposition region 472 to a second non-deposition region 474 adjacent to a second gas distribution plate 430b. In the embodiment of FIG. 4, the second direction moves the substrate 60 vertically. The first non-deposition region 472 and the second non-deposition region 474 are shown in the same space with one being an unbounded region above the other. The substrate is then moved laterally in a third direction 443 which is perpendicular to the second direction 442 and parallel to and opposite from the first direction 441. In the third direction 443, the substrate 60 moves from the second non-deposition region 474 through a second deposition region 475 to a third non-deposition region 476 on an opposite side of the second deposition region 475 from the second non-deposition region 474. In passing through the second deposition region 475, at least a second layer is deposited onto the surface of the substrate 60. In detailed embodiments, after passing through the second deposition region 475, there are in the range of about 20 to about 80 layers deposited on the surface of the substrate 60.

The embodiment shown in FIG. 4 also includes a load lock chamber 410 to transfer substrates 60 into and out of the processing chamber 420. Substrates 60 are moved into the load lock chamber 410 by one or more robots configured to safely transport the substrates 60. The substrate 60 is loaded 411 into the loading region 471 of the processing chamber 420 from the load lock chamber 410 and is unloaded 412 from the third non-deposition region 476 after processing is complete.

In some embodiments, the substrate 60 is moved from the third non-deposition region 476 in a fourth direction 444 on stage 481 opposite the second direction 442. In doing so, the substrate 60 moved from the third non-deposition region 476 back to the loading region 471. The movements in the first direction 441, second direction 442 and third direction 443 are then repeated to move the substrate 60 back to the third non-deposition region 476. Detailed embodiments further comprise removing the substrate 60 from the processing chamber 420 after the substrate 60 has reached the third non-deposition region 476 a second time. However, it should be understood that the movement in the fourth direction 444 can be repeated any number of times, resulting in multiple passes through the first deposition region 473 and the second deposition region 475 to deposit more layers onto the substrate 60.

FIG. 5 shows another embodiment of the invention in which the second direction 442 is perpendicular to the first direction 441 and both the first direction 441 and the second direction 442 are horizontal. This results in multiple gas distribution plates 430 next to each other. In these embodiments, the gas distribution plates 430 are aligned horizontally and the stage 480 is configured to move horizontally.

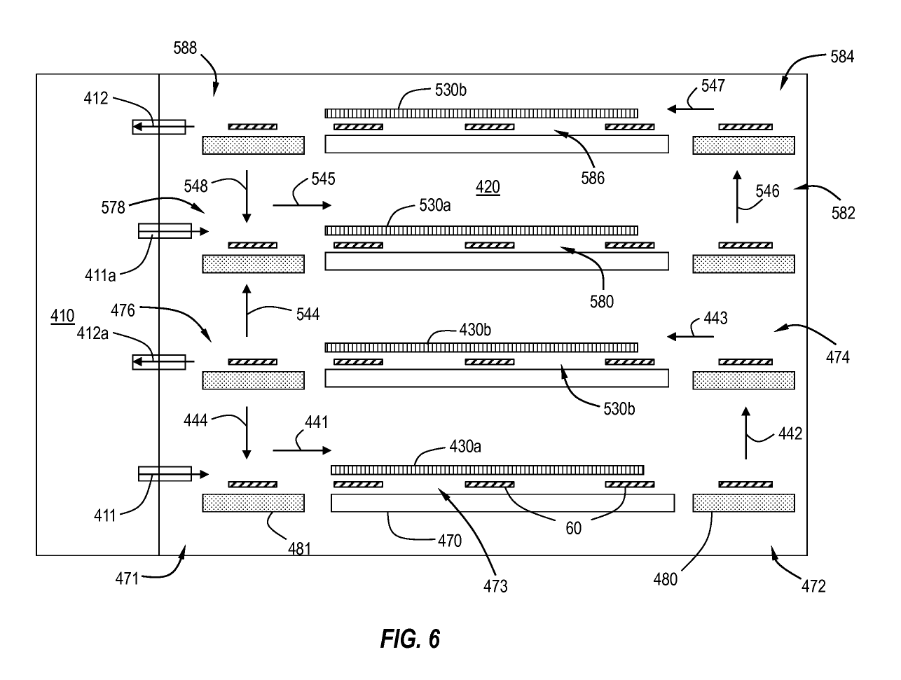

FIG. 6 shows another embodiment of the invention in which four gas distribution plates are incorporated. This embodiment is an extension of the processing chamber shown in FIG. 4 and uses all of the reference numerals and associated descriptions. In this embodiment, after the substrate 60 has reached the third non-deposition region 476, the route taken can be varied. For example, the substrate 60 can follow fourth direction 444 on the stage 481 to repeat deposition at the first gas distribution plate 430a and the second gas distribution plate 430b to return to the third non-deposition region 476. The substrate 60 can also be moved from the third non-deposition region 476 in a fourth direction 544, perpendicular to the third direction 443, on the stage 481 to a fourth non-deposition region 578. The substrate 60 is then laterally moved from the fourth non-deposition region 578 in a fifth direction 545. The fifth direction 545 can be parallel to the first direction 441, or horizontal but perpendicular to the first direction 441. In moving in the fifth direction 545, the substrate 60 is moved from the fourth non-deposition region 578 through a third deposition region 580 adjacent the third gas distribution plate 530a to a fifth non-deposition region 582. The substrate 60 is then moved on stage 481 in the sixth direction 546, perpendicular to the fifth direction 545, from the fifth non-deposition region 582 to the sixth non-deposition region 584. The substrate 60 is then laterally moved in the seventh direction 547 from the sixth non-deposition region 584 through the fourth deposition region 586 adjacent the fourth gas distribution plate 530b to the seventh non-deposition region 588. Once in the seventh non-deposition region 588, the substrate 60 can follow eighth direction 548 to the fourth non-deposition region 578 or can be unloaded 412 from the processing chamber 420.

The stage 480 can be one or more individual stages. When more than one stage is employed, the first moves between the first non-deposition region 472 and the second non-deposition region 474, and the second stage moves between the fifth non-deposition region 582 and the sixth non-deposition region 584. Similarly, when more than one stage 481 is employed, the first can move between and among the loading region 471, the third non-deposition region 476 and the fourth non-deposition region 578, and the second can move between and among the third non-deposition region 476, the fourth non-deposition region 578 and the seventh non-deposition region 588. It will be understood that the stages 480 and 481 can be controlled to provide a transition of substrates to the various gas distribution plates to maintain a continuous flow of substrates being processed. This coordination will depend on, for example, the speed of the conveyer system 470, the size of the substrates and the spacing between substrates.

In detailed embodiments, the second direction 442, fourth direction 544 and sixth direction 546 are vertical. In some embodiments, the second direction 442, fourth direction 544 and sixth direction 546 are horizontal.

Although the non-deposition regions are numbered individually, it should be understood that this is merely for descriptive purposes. The stage 480 and stage 481 may move between all of these regions freely as there may not be any physical impediment to doing so. In specific embodiments, there is a separator (not shown) between the second non-deposition region 474 and the fifth non-deposition region 582.

The embodiment shown in FIG. 6 can include enough gas ports to deposit several hundred layers on a substrate. In detailed embodiments, each of the plurality of gas ports can be individually controlled. Some of the gas distribution plates or individual gas ports can be configured to deposit films of different compositions, or can be disabled or set to deliver purge gases only.

Still referring to FIG. 6, one or more embodiments of the invention allow for the process chamber 420 to be effectively split into two. In some specific embodiments, when the substrate reaches the third non-deposition region 476, it can be unloaded 412a, or go through the lower cycle again. Additionally, a second substrate can be loaded 411 a into the fourth non-deposition region 578 to cycle through the upper portion of FIG. 6. Thus, two substrates, or sets of substrates can be processed simultaneously. Accordingly, a detailed embodiment of the invention has four gas distribution plates separated into a first group of two gas distribution plates and a second group of gas distribution plates. Therefore, a different set of substrates can be processed on the first group than the second group of gas distribution plates. In some embodiments, the set of substrates processed on the first group can be passed through the second group for additional processing, either the same layers being deposited or different layers.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

1. A deposition system for processing a substrate, comprising:
a processing chamber;
a plurality of gas distribution plates, each of the plurality of gas distribution plates having a plurality of elongate gas ports that direct flows of gases toward a surface of a substrate;
a load lock chamber connected to the processing chamber by an isolation valve that isolates the load lock chamber from the processing chamber during processing, the load lock chamber having a shuttle that loads the substrate into a front of a first of the plurality of gas distribution plates and that extracts the substrate from an end of a last of the plurality of gas distribution plates when the isolation valve is open;
a shuttle inside the processing chamber that moves the substrate from an end of one of the plurality of gas distribution plates to a front of another of the plurality of gas distribution plates.

2. The deposition system of claim 1, wherein the plurality of gas distribution plates includes one or more intermediate gas distribution plates

3. The deposition system of claim 2, wherein the one or more intermediate gas distribution plates are connected in series between an end of the first of the plurality of gas distribution plates and the front of the last of the plurality of gas distribution plates.

4. The deposition system of claim 1, comprising a robotic feed conveyor that feeds the substrates to the load lock chamber.

5. The deposition system of claim 3, wherein the plurality of gas distribution plates are stacked in a vertical arrangement and the shuttle moves vertically.

6. The deposition system of claim 3, wherein the plurality of gas distribution plates are aligned horizontally and the shuttle moves horizontally.

7. The deposition system of claim 1, wherein each of the plurality of gas distribution plates comprises a plurality of gas ports, each of the plurality of gas ports being able to be individually controlled.

8. The deposition system of claim 1, wherein at least one of the plurality of gas ports in each of the plurality of gas distribution plates is in flow communication with a first precursor gas and at least one of the plurality of gas ports in each of the plurality of gas distribution plates is in flow communication with a second precursor gas.

9. The deposition system of claim 1, further comprising:
a second plurality of gas distribution plates, each of the plurality of gas distribution plates having a plurality of elongate gas ports that direct flows of gases toward a surface of a substrate; and
a second shuttle inside the processing chamber that moves the substrate from an end of one of the second plurality of gas distribution plates to a front of another of the second plurality of gas distribution plates.

10. The deposition system of claim 9, wherein the first plurality of gas distribution plates processes substrates differently than the second plurality of gas distribution plates.

11. A method of processing a substrate in a processing chamber, the method comprising:
conveying the substrate to a load lock chamber with a robotic conveyor;
opening an isolation valve in the load lock chamber;
conveying the substrate to a first gas distribution plate;
closing the isolation valve;
processing the substrate with gases from the first gas distribution plate;
conveying the substrate from the first gas distribution plate to a series of one or more additional gas distribution plates, each of the one or more additional gas distribution plates processing the substrate with gases; and
opening the isolation valve; and
conveying the substrate to the load lock chamber.

12. The method of claim 11, wherein the series of one or more additional gas distribution plates includes at least two gas distribution plates.

13. The method of claim 11, wherein the substrates are conveyed vertically between each of the gas distribution plates.

14. The method of claim 11, wherein the substrates are conveyed horizontally between each of the gas distribution plates.

15. The method of claim 11, wherein each of the gas distribution plates comprises a plurality of gas ports that are individually controlled to process the substrate.

16. The method of claim 15, wherein at least one of the plurality of gas ports in each of the gas distribution plates is in flow communication with a first precursor gas and at least one of the plurality of gas ports in each of the gas distribution plates is in flow communication with a second precursor gas.

17. A deposition system for processing a substrate, comprising:
a processing chamber;
a first, second, third and fourth gas distribution plates, each having a plurality of elongate gas ports configured to that direct flows of gases toward a surface of a substrate;
a load lock chamber connected to the processing chamber by an isolation valve that isolates the load lock chamber from the processing chamber during processing, the load lock chamber having a shuttle that loads the substrate into a front of the first gas distribution plate and that extracts the substrate from and end of the fourth gas distribution plate when the isolation valve is open;
a shuttle inside the processing chamber that moves the substrate from an end of the first gas distribution plate to a front of the second gas distribution plates, then from an end of the second gas distribution plate to a front of the third gas distribution plate and then from an end of the third gas distribution plate to a front of the fourth gas distribution plate,
wherein the substrate is processed by each of the first, second, third, and fourth gas distribution plates.

18. The deposition system of claim 17, comprising a robotic feed conveyor that feeds the substrates to the load lock chamber.

19. The deposition system of claim 17, wherein the first, second, third and fourth gas distribution plates are stacked in a vertical arrangement and the shuttle moves vertically.

20. The deposition system of claim 17, wherein the first, second, third, and fourth gas distribution plates are aligned horizontally and the shuttle moves horizontally.
